(19) United States
(12) Patent Application Publication
(10) Pub. No.: US 2014/0268598 A1
(43) Pub. Date: Sep. 18, 2014

(54) Electronic Device Having Connector With Integrated Shielding

(71) Applicant: Apple Inc., Cupertino, CA (US)

(72) Inventors: Jae Hwang Lee, San Jose, CA (US); Dominic E. Dolci, Berkeley, CA (US); Phillip S. Satterfield, Oakland, CA (US); George Tziviskos, San Jose, CA (US)

(73) Assignee: Apple Inc., Cupertino, CA (US)

(21) Appl. No.: 13/899,971

(22) Filed: May 22, 2013

Related U.S. Application Data
(60) Provisional application No. 61/794,844, filed on Mar. 15, 2013.

(51) Int. Cl. H01R 12/53; H05K 9/00; H01R 9/05

(52) U.S. Cl. CPC H01R 12/53; H01R 9/0515; H05K 9/0024
USPC 361/752; 439/583; 361/760; 361/783

(57) ABSTRACT

An electronic device may have a housing in which electrical components on a printed circuit board are mounted. A connector may be mounted to the edge of the printed circuit board using solder. The connector may have a threaded portion that protrudes through the housing. A threadless portion of the connector may be aligned with the housing. The connector may have a metal body member covered with a metal shell. The metal shell may have a portion that covers the electrical components and serves as an electromagnetic interference shield for the electrical components. The connector may have a threaded barrel. The threaded barrel may have a threaded outer portion with a diameter that is larger than a threaded inner portion. The threadless portion of the connector may lie between the threaded outer and inner portions.

This application claims priority to U.S. provisional patent application No. 61/794,844 filed Mar. 15, 2013, which is hereby incorporated by reference herein in its entirety.

### BACKGROUND

This relates generally to electronic devices and, more particularly, to connectors such as radio-frequency connectors for use in electronic devices.

Electronic devices often contain connectors. For example, electronic equipment may contain coaxial cable connectors that mate with coaxial cables. Coaxial cables are often used to convey radio-frequency signals such as video signals.

Components in electronic devices such as radio-frequency circuits may use electromagnetic interference (EMI) shielding structures. Electromagnetic interference shielding structures may help prevent radio-frequency signals that are generated by one component from disrupting the operation of another component that is sensitive to radio-frequency interference. Electromagnetic shielding structures may be formed from metal shielding cans soldered to printed circuit boards.

It can be challenging to mount connectors in electronic devices. Connectors that are not mounted to printed circuit boards are often cumbersome, because they may need to be secured to device housings using fasteners such as nuts and may require that solder connections be formed following attachment of the connector to the housing. Space is often at a premium in electronic devices, so mounting arrangements in which shielding structures and connectors compete for space on a printed circuit or in which connectors are bulky may not be acceptable.

It would therefore be desirable to be able to provide improved connectors for use in electronic devices.

### SUMMARY

An electronic device may have electrical components mounted on a printed circuit board. The printed circuit board may be mounted within a housing. A connector may be mounted to an edge of the printed circuit board using solder, so that a portion of the connector protrudes through an opening in the housing.

The protruding portion of the connector may be formed from a threaded barrel mounted in a connector body member. The threaded barrel may have a first threaded portion that is configured to mate with a coaxial cable connector. The threaded barrel may also have a second threaded portion that screws into a threaded opening in the connector body. A threadless portion of the threaded barrel between the first and second threaded portions may be aligned with the housing.

The connector body member may be covered with the metal shell. A portion of the metal shell may form an electromagnetic interference shielding cavity in which the electrical components are housed. By covering the electrical components with the electromagnetic interference shielding cavity formed from the metal shell, the metal shell may serve both as a portion of the connector and as an electromagnetic interference shielding structure for the electrical components.

The metal shell and the connector body may have aligned openings configured to receive a threaded set screw. The threaded barrel may have a flat area aligned with thread initiation and termination points. When the set screw bears against the flat area, the threaded barrel may be rotationally aligned so that the thread initiation and termination points are located out of view on the lower side of the threaded barrel.

Further features, their nature and various advantages will be more apparent from the accompanying drawings and the following detailed description of the preferred embodiments.

### BRIEF DESCRIPTION OF THE DRAWINGS

FIG. 1 is a perspective view of an illustrative electronic device of the type that may be provided with a connector in accordance with an embodiment.

FIG. 2 is a top interior view of an illustrative electronic device with a connector having one end that extends through a housing wall and an opposing end that has been mounted to a printed circuit board in accordance with an embodiment.

FIG. 3 is a perspective view of an edge portion of a printed circuit board to which a connector has been mounted using solder in accordance with an embodiment.

FIG. 4 is a top view of the interior of a corner portion of an electronic device having a connector mounted to a printed circuit board with an extended portion that serves as an electromagnetic interference shield for shielding electrical components on the printed circuit board in accordance with an embodiment.

FIG. 5 is an exploded perspective view of an illustrative connector in accordance with an embodiment.

FIG. 6 is a top exploded perspective view of a partially assembled version of the illustrative connector of FIG. 5 showing how the connector may include a connector body assembly, a threaded barrel that is received within a threaded opening in the body assembly, and a set screw in accordance with an embodiment.

FIG. 7 is a perspective view of the illustrative connector of FIGS. 5 and 6 following installation of the threaded barrel and set screw into the connector body assembly in accordance with an embodiment.

FIG. 8 is a bottom exploded perspective view of the illustrative connector of FIG. 5 showing how the connector may include a connector body assembly that has a threaded opening for receiving a set screw that secures the threaded barrel in accordance with an embodiment.

FIG. 9 is a bottom perspective view of the illustrative connector of FIG. 8 following assembly in accordance with an embodiment.

FIG. 10 is a perspective view of a portion of the threaded barrel of an illustrative connector showing the locations of thread initiation and thread termination locations on the barrel in accordance with an embodiment.

FIG. 11 is a cross-sectional side view of a portion of a connector showing how thread initiation and thread termination locations on a threaded barrel in the connector may be configured to face downwards out of view of a user of an electronic device in accordance with an embodiment.

### DETAILED DESCRIPTION

An electronic device may be provided with electronic components such as integrated circuits. These components may be mounted on a printed circuit board. Connectors may also be mounted on the printed circuit board. For example, a coaxial cable connector or other connector for mating with an external cable may be mounted on an edge of a printed circuit board. The connector may include integral electromagnetic interference shielding structures for shielding some of the electronic components on the printed circuit board. As an example, an amplifier integrated circuit that is used in amplifying signals passing through the connector may be shielded using the integral electromagnetic interference shielding structures. The connector may also have features to minimize size and improve device aesthetics.

An illustrative electronic device of the type that may be provided with a printed circuit board connector is shown in FIG. 1. Electronic device 10 of FIG. 1 has openings 14 in housing 12. Openings 14 form connector ports for connectors such as Ethernet plugs, Universal Serial Bus connectors, power connectors, audio jacks, connectors for coaxial cables for television signals and other signals, and other connectors. Housing 12, which may sometimes be referred to as an enclosure or case, may be formed of plastic, glass, ceramics, fiber composites, metal (e.g., stainless steel, aluminum, etc.), other suitable materials, or a combination of any two or more of these materials. Housing 12 may be formed using a unibody configuration in which some or all of housing 12 is machined or molded as a single structure or can be formed using multiple structures (e.g., an internal frame structure, one or more structures that form exterior housing surfaces, etc.).

Electronic device 10 of FIG. 1 may be a set-top box, a wireless access point, a router, a storage device, a device for providing still and moving images to an attached display such as a television or computer monitor, a cellular telephone, a handheld portable device such as a media player, a somewhat smaller portable device such as a wrist-watch device, a pendant device, other wearable or miniature device, gaming equipment, tablet computer, notebook computer, desktop computers, television, computer monitor, a computer integrated into a computer display, a hybrid device that includes the functionality of two or more devices such as these, or other electronic equipment. The use of a set-top box form factor of the type shown in the example of FIG. 1 in implementing device 10 is merely illustrative.

Device 10 may include internal structures such as printed circuits. Electrical components may be mounted on the printed circuits and may be electrically connected through conductive paths in the printed circuits and in external cables. Printed circuits in device 10 may include rigid printed circuit boards (e.g., printed circuits formed from fiberglass-filled epoxy or other rigid substrate material) and/or flexible printed circuits (e.g., printed circuit substrates formed from flexible polymer layers such as sheets of polyimide).

Components that may be mounted on the printed circuits include power supply components, inductors, capacitors, resistors, integrated circuits such as amplifiers and other integrated circuits, switches, connectors, sensors, wireless circuits, and other electrical components. Some of these components and the printed circuits on which the components are mounted may be mounted within the interior of a shielding enclosure that is formed as part of a connector. The connector may be, for example, be a printed circuit board connector that is mounted on the edge of one of the printed circuit boards in device 10. With one suitable configuration, which is sometimes described herein as an example, the connector may be a coaxial cable connector such as connector 16 of FIG. 1

Coaxial cable connector 16 may be a female coaxial cable F connector or other connector suitable for coupling to external cables such as coaxial cable 26. Cable 26 may be terminated in a male coaxial cable F connector 22 or other suitable male cable connector. Connector 22 may have a threaded grounded body 24 that surrounds central positive signal pin 20. Signal pin 20 in male connector 22 may be a protruding center conductor associated with coaxial cable 26. Threaded male connector body 24 may screw onto mating threads in a threaded barrel in connector 16 (see, e.g., the protruding cylindrical portion of connector 16 that protrudes through the circular opening 14 in housing 12 in the FIG. 1 example). When male connector 22 is installed on female connector 16 of device 10 in this way, male connector pin 20 will be received within center conductor 18 of female connector 16.

A top view of an interior portion of electronic device 10 is shown in FIG. 2. As shown in FIG. 2, printed circuit board 28 may be mounted in the cavity formed in the interior of housing 12. Electrical components 30 may be mounted on printed circuit board 28. Electrical components 30 may include integrated circuits, discrete components such as resistors, capacitors, and inductors, switches, application-specific integrated circuits, processor circuits, storage, video processing circuitry, wireless transceiver circuitry, and other circuitry. Components 30 may be interconnected with each other and connectors such as connector 16 using wires, metal traces in printed circuit board 28, flexible printed circuit cables, coaxial cables, and other signal path structures. For example, a microstrip transmission line or other transmission line formed from metal traces on printed circuit board 28 such as transmission line path 32 may be used to route signals between the circuitry of components 30 and connector 16.

Connector 16 may have a portion such as portion 34 that protrudes from housing 12. Portion 34 may include the tip of a threaded barrel. Connector 16 may also have a portion such as portion 36 (sometimes referred to as a connector body assembly) that is mounted on printed circuit 28 and that is housed within the interior of housing 12.

FIG. 3 is a perspective view of an edge portion of printed circuit board 28 showing how connector 16 may be mounted to printed circuit board 28. Printed circuit board 28 may be formed from a rigid printed circuit board substrate material such as fiberglass-filled epoxy. Metal traces in printed circuit board 28 such as metal traces 32A and 32B may be used to form transmission lines and other signal paths. In transmission line path 32, for example, metal trace 32A may form a positive transmission line conductor and metal trace 32B may form a ground transmission line conductor (as an example). Metal trace 32A and other positive signal conductors associated with connector 16 may be coupled to positive connector center contact 18. Metal trace 32B and other ground signal conductors associated with connector 16 may be coupled to metal threads 44 in portion 34 of connector 16.

Body assembly (body structures) 36 of connector 16 may include a body member such as body 40 (e.g., a cast or machined member formed from stainless steel, brass, or other metal) covered with a stamped metal shell such as stainless steel shell 38 or a metal shell formed from other metals. Metal trace 32B may be shorted to metal shell 38 in connector body assembly 36 using solder pad portion 32B′ of metal trace 32B and solder 42. The solder joint formed from solder 42 may attach connector 36 to printed circuit board 28. Attachment mechanisms such as screws or other fasteners, welds, mounting brackets, adhesive, and other mounting structures may be used, if desired. By attaching connector 16 to board 28 prior to insertion of printed circuit board 28 into housing 12, potentially cumbersome operations associated with wiring a separate connector to traces 32A and 32B after board installation can be avoided.

FIG. 4 is a top interior view of a corner portion of electronic device 10 showing how portion 34 of connector 16 may extend through opening 14 in the wall of housing 12 to expose threads 44. Threads 44 may lie within protruding threaded portion 70. Threadless portion 72 of connector 16 may be aligned with opening 14 in housing 12 (i.e., threadless portion 72 overlaps the wall in housing 12). Conductive paths such as ground conductive path 32B″ may couple threads 44 of connector 16 to metal shell 38 and other grounded elements. Conductive paths such as positive signal path 32A″ may be coupled to center conductor terminal 18 (i.e., the positive terminal of connector 16).

The signals on positive line 32A″ and ground line 32B″ may be routed to respective positive signal path 32A and ground path 32B via one or more electrical components 30′. Electrical components 30′ may be mounted on printed circuit board 28 under a portion of metal shell 38. Electrical components 30′ may include amplifier circuitry, filter circuitry, and other circuitry for enhancing signal strength and quality. Electrical components 30′ may, for example, include one or more integrated circuits (e.g., amplifier integrated circuits) and discrete components such as capacitors, inductors, and resistors.

The circuitry formed from electrical components 30′ may produce electromagnetic interference signals that have the potential to interfere with other components 30 in device 10 such as other components 30 on printed circuit board 28. There is also a potential for electromagnetic signal interference that is generated by components 30 to interfere with the operation of electrical components 30′. By mounting components 30′ under metal connector shell 38, metal connector shell 38 may serve as an electromagnetic interference shielding structure that helps shield components 30′ from interference from components 30 and that helps shield components 30 from interference from components 30′.

FIG. 5 is an exploded perspective view of connector 16. As shown in FIG. 5, connector 16 may include threaded barrel 68. Barrel 68 may be formed from metals such as brass or stainless steel (as examples). Barrel 68 may be provided with threads such as threads 44 to mate with threaded connector member 24 in cable connector 22 (FIG. 1). For example, threads 44 may be configured to form a female coaxial cable F connector that mates with a corresponding male coaxial cable F connector. Barrel 68 may also be provided with threads 78 that mate with a threaded cylindrical opening in connector body 40. Threaded barrel 68 may have portions with different outer diameters. Threaded portion 70 may, for example, have a larger diameter than threaded portion 78.

A portion such as threadless portion 72 may be formed between threaded portions 70 and 74, if desired.

When mounted in device 10, portion 72 may be aligned with the wall of housing 12. By ensuring that portion 72 is bare of threads, tight tolerances (small gaps) may be established between barrel 68 and the opening (opening 14) in housing 12 through which barrel 68 passes.

Threaded barrel 68 may have an opening such as opening 76 into which center contact components 56 are mounted. Components 56 may include metal center contact pin 58, hollow metal rod 60, springs 62 and 64, and hollow dielectric cylinder (sheath) 66. When assembled, springs 62 and 64 may be inserted into opposing ends of hollow metal rod 60. Spring 62 receives one end of metal pin 58. The opposing end of metal pin 58 may form positive signal path 32A″ of FIG. 4. When connector 22 is screwed onto threads 44 of connector 16, center conductor 20 of connector 22 will be received within spring 64. Dielectric cylinder 66 shields the center conductor contact of connector 16 from the ground contact formed from barrel 68.

When assembled to form a completed connector, components 56 and threaded barrel 68 are mounted in connector body 40. Body 40 may be formed from a brass member, a stainless steel member, or other metal structure (as examples). Threaded barrel 68 may be held in place within body 40 using set screw 54.

Metal shell 38 may have a portion such as portion 50 that is configured to receive metal body 40. Metal shell 38 may also have portion 52 that serves as an electromagnetic interference shield that overlaps and shields electrical components 30′ on printed circuit board 28. In region 52, the lower edge of shell 38 may have a straight surface to facilitate formation of solder joints such as solder joint 42 of FIG. 3. In the illustrative example of FIG. 5, shell 38 has optional prong 48. Prong 48 may be received within a mating hole in printed circuit board 28. In configurations in which prongs such as prong 48 are provided on shell 38, the prongs may help secure connector 16 to printed circuit board 28. If desired, the lower edge of shell 38 in region 52 may be provided with protrusions 46 (e.g., castellation features) as shown in the example of FIG. 5 to help reduce solder wicking.

FIG. 6 is a partially exploded top perspective view of connector 16. As shown in FIG. 6, threads 78 of reduced diameter portion 74 of threaded barrel 68 may be received by corresponding threaded cylindrical opening 80 in body 40 of connector body assembly 36. Set screw 54 may be used to secure threaded barrel 68 after threaded barrel 68 has been screwed into opening 80. Because the diameter of internal threaded portion 74 of connector 16 is smaller than the diameter of external threaded portion 70 of connector 16, the volume of body member 40 that is required to form threaded cylindrical opening 80 in body 40 can be reduced, thereby helping to ensure that connector 16 is not overly bulky. The diameter of external threaded portion 70 may be configured to mate with ground connector portion 24 of connector 22. For example, if connector 22 is a male cable F connector, threaded portion 70 may be sized to form a mating female F connector.

FIG. 7 is a top perspective view of connector 16 of FIG. 6 following assembly of connector 16 by screwing threaded barrel 68 into opening 80 in the front face of body 40 and after screwing set screw 54 into a corresponding threaded opening in the lower surface of body 40.

FIG. 8 is a partially exploded bottom perspective view of connector 16 showing how opening 82 of connector body assembly 36 may be formed by aligned circular openings in shell 38 and connector body 40. Set screw 54 may have threads that are received by corresponding threads within body assembly opening 82 (i.e., threads formed on the inner walls of the cylindrical opening in body 40). Threaded barrel 68 may have a flattened portion such as flat area 84 in reduced-diameter threaded region 74. Set screw 54 may bear against flat portion 84 of threaded barrel 68 when barrel 68 is screwed into connector body assembly 36. This helps ensure that barrel 68 is assembled with a desired rotational orientation with respect to rotational axis 86 of barrel 68.

FIG. 9 is a bottom perspective view of connector 16 of FIG. 8 following assembly of connector 16. In the configuration of FIG. 9, threaded barrel 68 has been screwed into threaded opening 80 in connector body assembly 36 (FIG. 6) and set screw 54 has been screwed into set screw opening 82 in connector body assembly 36 (FIG. 8). As shown in FIG. 9, stamped metal shell 38 contains portions such as shielding portion 52 with sidewalls 93 and upper wall 95 that define an internal electromagnetic interference shielding cavity (cavity 91) for receiving and shielding components 30′ on printed circuit board 28. Cavity 91 may have a rectangular box shape (e.g., in arrangements of the type shown in FIG. 9 in which shell 38 forms an upside-down open box) or may have other shapes (e.g., shapes with curved edges, shapes with more than one cavity height above printed circuit board 28, etc.). The configuration of FIG. 9 is merely illustrative.

As shown in FIG. 10, external threaded portion 70 of threaded barrel 68 may have threads 44. Threads 44 may start and end at locations such as locations 88 and 90. Locations 88 and 90 may sometimes be referred to as thread initiation and termination discontinuities, thread discontinuities, thread endpoints, or thread initiation and termination points. For example, location 88 may be referred to as a thread initiation discontinuity (i.e., a point at which threads 44 start along the length of barrel 69 parallel to rotational axis) and location 90 may be referred to as a thread termination discontinuity (i.e., a point at which threads 44 finish).

The presence of thread initiation and termination points in threads 44 may be unsightly to a user of device 10. As shown in FIG. 11, thread initiation and termination points 88 and 90 may be hidden from view by locating thread initiation and termination points 88 and 90 on the underside of threaded barrel 68 in alignment with flat area 84. When set screw 54 bears against flat area 84, the rotational orientation of threaded barrel 68 about rotational axis will be established so that thread initiation and termination points 88 and 90 will be located on the underside of barrel 68 and connector 16, hidden from view.

The foregoing is merely illustrative and various modifications can be made by those skilled in the art without departing from the scope and spirit of the described embodiments. The foregoing embodiments may be implemented individually or in any combination.

What is claimed is:

1. A connector, comprising:
a threaded barrel having a first threaded portion with a first diameter that is configured to mate with a coaxial cable connector and a second threaded portion with a second diameter that is smaller than the first diameter; and
body structures having a threaded opening that receives the second threaded portion.

2. The connector defined in claim 1 wherein the body structures include a metal shell.

3. The connector defined in claim 2 wherein the metal shell is configured to form an electromagnetic interference shielding cavity.

4. The connector defined in claim 3 wherein the body structures include a body member mounted in the metal shell.

5. The connector defined in claim 4 wherein the metal shell and the body member have aligned openings.

6. The connector defined in claim 5 further comprising a set screw in the aligned openings.

7. The connector defined in claim 6 wherein the second threaded portion has a flat area and wherein the set screw bears against the flat area.

8. The connector defined in claim 7 wherein the first threaded portion has threads with a thread initiation point and a thread termination point and wherein the thread initiation point and the thread termination point are located out of view on a lower portion of the first threaded portion when the set screw bears against the flat area.

9. The connector defined in claim 4 wherein the body member comprises a metal member with a threaded opening that receives the second threaded portion.

10. Apparatus, comprising:
a printed circuit board;
electrical components mounted on the printed circuit board; and
a connector having a metal shell that forms an electromagnetic interference shielding cavity covering at least some of the electrical components.

11. The apparatus defined in claim 10 wherein the electrical components include at least one integrated circuit.

12. The apparatus defined in claim 11 wherein the connector comprises a threaded barrel configured to mate with a coaxial cable connector and wherein the integrated circuit comprises an amplifier.

13. The apparatus defined in claim 10 further comprising:
a threaded metal barrel that is configured to mate with a coaxial cable connector;
a metal body in at least part of the metal shell.

14. The apparatus defined in claim 13 wherein the threaded metal barrel has a first threaded portion with a first diameter and a second threaded portion with a second diameter that is smaller than the first diameter.

15. The apparatus defined in claim 14 wherein the metal body has a threaded opening that receives the second threaded portion.

16. An electronic device, comprising:
a printed circuit;
electrical components on the printed circuit;
a housing with an opening; and
a connector that is mounted on the printed circuit, wherein the connector has a threaded barrel with a first threaded portion, a second threaded portion, and a threadless portion between the first and second threaded portions, and wherein the connector protrudes through the opening so that the threadless portion is aligned with the housing.

17. The electronic device defined in claim 16 wherein the first threaded portion has a diameter that is larger than the second threaded portion and wherein the connector has a connector body with a threaded opening that receives the second threaded portion.

18. The electronic device defined in claim 17 wherein the connector has a metal shell that forms an electromagnetic interference shielding cavity covering the electrical components.

19. The electronic device defined in claim 18 wherein the electrical components include an amplifier.

20. The electronic device defined in claim 19 wherein the first threaded portion is configured to mate with a coaxial cable F connector, the electronic device further comprising solder that attaches the metal shell to an edge of the printed circuit.
